(19) United States
(12) Patent Application Publication
(10) Pub. No.: US 2014/0254742 A1
(43) Pub. Date: Sep. 11, 2014

(54) DELAY MEASUREMENT DEVICE, METHOD AND MEDIUM

(71) Applicant: FUJITSU LIMITED, Kawasaki-shi (JP)

(72) Inventor: Yoji SHIMAZAKI, Kawasaki (JP)

(73) Assignee: FUJITSU LIMITED, Kawasaki-shi (JP)

(21) Appl. No.: 14/281,203

(22) Filed: May 19, 2014

Related U.S. Application Data
(63) Continuation of application No. PCT/JP2011/076836, filed on Nov. 21, 2011.

(51) Int. Cl. G04F 10/04; G01R 31/26

(52) U.S. Cl. CPC G04F 10/04; G01R 31/2607
USPC 377/20

(57) ABSTRACT

An electronic circuit delay measurement device that includes: a delay section configured by a loop that reduces a pulse width of an input pulse by a specific reduction time and outputs the pulse, and that is connected such that the output pulse is employed as input; a pulse output section that is provided in the delay section loop, and that outputs a pulse of pulse width determined according to a delay time of an electronic circuit of a delay time measurement target when provided with a signal for starting a delay measurement, and that, for a pulse that has been input, outputs a pulse of pulse width determined according to the delay time of the electronic circuit; and a counting section that counts a pulse number of pulses output from the pulse output section.

### CROSS-REFERENCE TO RELATED APPLICATION

This application is a continuation application of International Application No. PCT/JP/2011/076836, filed Nov. 21, 2011, the disclosure of which is incorporated herein by reference in its entirety.

### FIELD

The present invention relates to an electronic circuit delay measurement device, method and medium, for measuring delay times of electronic circuits.

### BACKGROUND

Checking the delay of semiconductor circuits has recently become important, such as in operation checks of semiconductor circuits such as integrated circuits. For example, for circuits where a portion of the circuit, or all of the circuit is a semiconductor circuit, such as an integrated circuit, technology is known for detecting whether or not a signal delay has occurred, in order change operation according to the presence or absence of a delay in a circuit. This technology monitors for the occurrence of signal delays corresponding to malfunction, and is applicable to good-no good determination of semiconductor circuits such as integrated circuits.

However, along with increasing operation speeds of semiconductor circuits such as integrated circuits, it has become important to ascertain the delay times of semiconductor circuits themselves, in order to ascertain the performance of semiconductor circuits such as integrated circuits.

Therefore, as technology to measure the delay time for a portion of circuits or all circuits of a semiconductor circuit, measurement devices are known that employ ring oscillators. Ring oscillators are an odd number of measurement target circuits connected together in series, configured in a ring shape with the input terminal connected to the output terminal In measurement of delay times using ring oscillators, first the cycle of the ring oscillators is measured from the output frequency. Then, the measured cycle is divided by the number of stages in the measurement target circuit that is configured by the ring oscillator. As a result, this thereby enables the delay time of one stage of the measurement target circuit to be derived.

More specifically, in an odd number (n individual, wherein n is an odd number) of individual measurement target circuits, a branch is taken off from the output terminal of the ring oscillator where the input terminal and the output terminal are connected together, and the branch is connected to a frequency measurement device. A pulse is then output from the ring oscillator with cycle of twice the delay time (Tdrosc) according to the n-stages of the measurement target circuit. Namely, if the frequency measured by the frequency measurement device is denoted f, then the cycle is 1/f (=2·Tdrosc), and a pulse is output with a frequency f of 1/(2·Tdrosc). Thus the delay time of the ring oscillator is not directly measured, but rather the frequency f of the output pulse is measured external to the ring oscillator with the frequency measurement device connected to the branch. A delay time per measurement target circuit stage Td (=Tdrosc/n=1/2 nf) can be obtained from the result arrived at by dividing the frequency, f, by the number of connected measurement target circuit stages, n.

In principle the ring oscillator may be formed using any number of stages, as long as n here is an odd number. However, when for example the measurement target circuits are inverters, the delay time expected in the latest technology is 20 ps (about 50 GHz), meaning that a special high frequency measurement device needs to be prepared, and making simple frequency measurement difficult to perform. As a countermeasure thereto, adjustment is made to lower the operation frequency of the ring oscillator by increasing the number of stages n, and measurement is then performed. Lowering the operation frequency of the ring oscillator enables operation frequency measurement to be performed easily.

Moreover, accompanying increased operational speeds of semiconductor circuits such as integrated circuits, technology is also known that determines whether or not signal delay has occurred.

### RELATED PATENT DOCUMENTS

Patent Document 1: Japanese Patent Application Laid-Open (JP-A) No. 2008-256491

Patent Document 2: JP-A No. H05-34418.

### SUMMARY

According to an aspect of the embodiments, an electronic circuit delay measurement device includes: a delay section configured by a loop that reduces a pulse width of an input pulse by a specific reduction time and outputs the pulse, and that is connected such that the output pulse is employed as input; a pulse output section that is provided in the delay section loop, and that outputs a pulse of pulse width determined according to a delay time of an electronic circuit of a delay time measurement target when provided with a signal for starting a delay measurement, and that, for a pulse that has been input, outputs a pulse of pulse width determined according to the delay time of the electronic circuit; and a counting section that counts a pulse number of pulses output from the pulse output section.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating a schematic configuration of a semiconductor circuit delay measurement device according to a first exemplary embodiment;

FIG. 2 is a diagram to explain the input of a pulse to, and the output of a pulse from, a delay circuit;

FIG. 3 is a circuit diagram illustrating an example of a configuration to induce a difference between the rise and fall delay times;

FIG. 4 is a circuit diagram illustrating an example of a configuration to induce a difference between the rise and fall delay times, either stepwise or selectively;

FIG. 5 is a circuit diagram illustrating an example of a configuration of the chopper circuit operated by pulse fall according to the first exemplary embodiment;

FIG. 6 is a circuit diagram illustrating an example of a modified example of FIG. 5;

FIG. 7 is an explanatory diagram of delay time measurement employing the semiconductor circuit delay measurement device according to the first exemplary embodiment;

FIG. 8 is a timing chart of the chopper circuit of a delay measurement circuit;

FIG. 9 is a circuit diagram illustrating an example of a configuration of a chopper circuit operated by pulse rise according to a second exemplary embodiment;

FIG. 10 is a circuit diagram illustrating an example of a modified example of FIG. 9;

FIG. 11 is an explanatory diagram of delay time measurement employed in the semiconductor circuit delay measurement device according to the second exemplary embodiment;

FIG. 12 is a block diagram illustrating a schematic configuration of a delay measurement device serving as an example of an electronic circuit delay measurement device according to a third exemplary embodiment;

FIG. 13 is a flow chart illustrating flow in delay time measurement processing executed by a semiconductor circuit delay time measurement device according to the third exemplary embodiment;

FIG. 14 is a circuit diagram illustrating an example of a configuration of the chopper circuit according to a fourth exemplary embodiment;

FIG. 15 is a circuit diagram of an example of a configuration of a chopper circuit operated by pulse fall according to a fifth exemplary embodiment;

FIG. 16 is a circuit diagram illustrating an example of a modified example of FIG. 15;

FIG. 17 is an explanatory diagram of delay time measurement employed in the semiconductor circuit delay measurement device according to the fifth exemplary embodiment;

FIG. 18 is a circuit diagram illustrating an example of a configuration of the chopper circuit operated by pulse rise according to a sixth exemplary embodiment;

FIG. 19 is a circuit diagram illustrating an example of a modified example of FIG. 18; and

FIG. 20 is an explanatory diagram of delay time measurement employing the semiconductor circuit delay measurement device according to the sixth exemplary embodiment.

### DESCRIPTION OF EMBODIMENTS

Detailed explanation follows regarding an example of exemplary embodiments of technology disclosed herein, with reference to the drawings.

### First Exemplary Embodiment

FIG. 1 illustrates a schematic configuration of a semiconductor circuit delay measurement device 10 that is an example of an electronic circuit delay measurement device according to the present exemplary embodiment. The semiconductor circuit delay measurement device 10 is equipped with a delay circuit 12 that serves as a delay section and includes m individual inverters 12A connected together in series (m is an even number). Namely, in the present exemplary embodiment, the delay circuit 12 has positive logic. The input side and the output side of the delay circuit 12 are connected, so as to form a ring shape. Note that in the example of FIG. 1, explanation follows regarding the delay circuit 12 and a case of m individual inverters 12A connected together in series, however NAND devices may be employed in place of the inverters 12A. Between the input side and the output side of the delay circuit 12A, a chopper circuit 14, serving as a pulse output section, is provided with a control terminal 20 applied with a signal for starting delay measurement. The input side of the chopper circuit 14 is connected to the output side of the delay circuit 12. The output side of the chopper circuit 14 is connected to the input side of the delay circuit 12, and also connected to the input side of a counter circuit 16 that serves as a counting section.

For example, the semiconductor circuit delay measurement device 10 may be directly mounted on a semiconductor circuit such as a substrate.

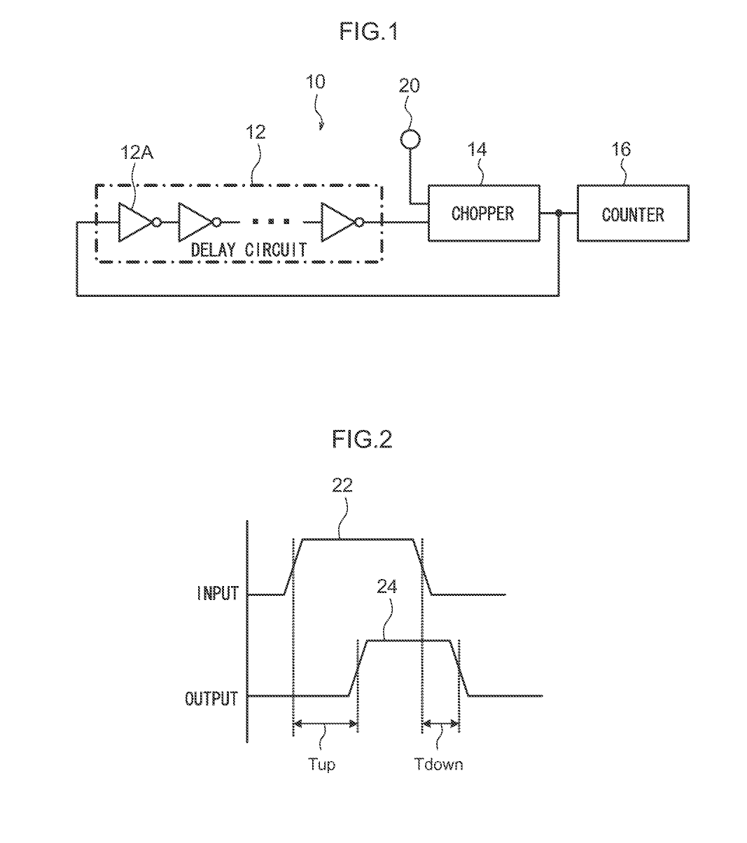

FIG. 2 illustrates diagrammatically the input of a pulse to the delay circuit 12 and the output of a pulse therefrom. The delay circuit 12 outputs the input pulse delayed by a given delay time (for example a predetermined delay time). In the present exemplary embodiment, configuration is made such that the delay times between respective pulse rises and respective pulse falls are made different from each other. Namely, the pulse 22 input to the delay circuit 12 is output as a pulse 24, delayed by a given period of time. In FIG. 2 the delay time between pulse rises is delay time Tup, and the delay time between pulse falls is delay time Tdown.

An example is given here of a case in which the delay times are made different from each other such that the delay time Tdown is shorter than the delay time Tup (Tup>Tdown). Note that there are cases in which the delay times are made different from each other such that the delay time Tdown is longer than the delay time Tup (Tup<Tdown). These differences in delay time depend on the configuration of the chopper circuit 14, described later. A difference may be induced between the delay time Tup and the delay time Tdown by adjusting the configuration of the delay circuit 12, namely by adjusting the balance between P channels and N channels of the semiconductor circuit. The respective delay times for the delay time Tup and the delay time Tdown can be adjusted by such balance adjustments.

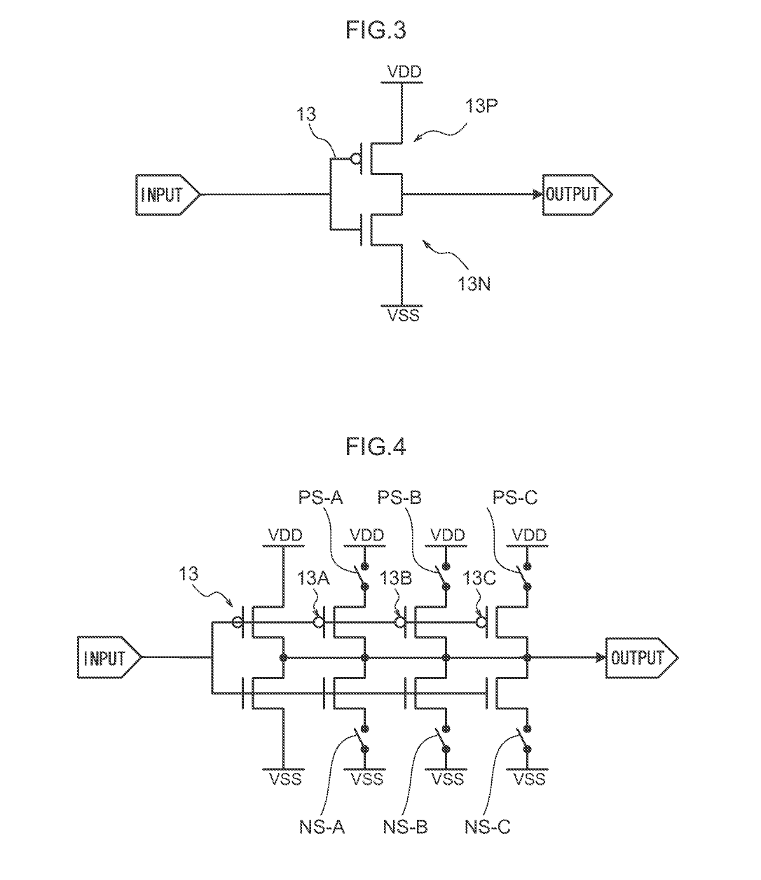

FIG. 3 illustrates an example of a CMOS inverter 13 as the inverter 12A, configured to induce a difference between the delay time Tup and the delay time Tdown. Note that in the drawings VDD and VSS denote a power source. In this CMOS inverter 13, the conductance of P channels and N channels are adjusted in order to induce a difference in delay time. Namely, a conductance Gmp of a PMOS-FET 13P and a conductance Gmn of an NMOS-FET 13N are adjusted.

Specifically, configuring such that the conductance matches (Gmp=Gmn) leads to the delay time Tup and the delay time Tdown also matching (Tup=Tdown). Moreover, the delay time Tup is made shorter (i.e. Tup<Tdown) by making the conductance Gmp of a PMOS-FET 13P larger than the conductance Gmn of an NMOS-FET 13N (Gmp>Gmn). However, the delay time Tdown is made shorter (i.e. Tup>Tdown) by making the conductance Gmp of the PMOS-FET 13P smaller than the conductance Gmn of the NMOS-FET 13N (Gmp<Gmn). It is possible to adjust the delay time itself by adjusting the values of these conductances. Namely, it is possible to produce circuits after determining the delay times and delay time difference during circuit design.

In the present exemplary embodiment, the difference in delay time between the pulse rise and pulse fall (the difference between the delay time Tup and the delay time Tdown) is adjusted in the direction such that the chopper circuit 14 makes the chop width narrower. Namely, such that the pulse width (chop width) of the pulse output from the chopper circuit 14, functioning as a pulse output section, described later, is reduced by the delay time difference (Tdiff=Tup−Tdown).

FIG. 4 illustrates an example of a configuration to induce a difference between the delay time Tup and the delay time Tdown, either stepwise or selectively. Explanation follows regarding an example of a circuit in which 4 of the CMOS gate structures illustrated in FIG. 3 are connected together in parallel. Note that although explanation here is for 4 CMOSs, configuration may be made with 5 or more, or 3 or less CMOSs. The circuit in FIG. 4 is configured with by the CMOS inverter 13 of FIG. 3, to which CMOS inverters 13A, 13B, 13C of similar configuration are connected in parallel. The PMOS-FET side of each of the CMOS inverters 13A, 13B, 13C is connected through respective switches PS-A, PS-B, PS-C to a power source VDD. The NMOS side of each of the CMOS inverters 13A, 13B, 13C is connected through respective switches NS-A, NS-B, NS-C to the power source VSS.

It is possible to specify conductance, either stepwise or selectively by selecting whichever of the switches PS-A, PS-B, PS-C of the PMOS-FET side, and the switches NS-A, NS-B, NS-C of the NMOS-FET side. This thereby enable the delay time to be adjusted by flexible operation of the circuit. Note that these switches may be switched ON/OFF by a controller, or the numbers of FETs may be specified by circuit design.

FIG. 5 illustrates an example of a configuration of the chopper circuit 14. The example given in FIG. 5 illustrates a chopper circuit as a pulse output section operated by pulse fall. The chopper circuit 14 is configured by a chopper with chop width determined according to the delay time of a measurement target circuit 30. The chopper circuit 14 is configured from NAND devices 26 and 28, and the measurement target circuit 30. The input side of the chopper circuit 14 is connected to one input side of the NAND device 26, and the control terminal 20 is connected to the other input side thereof. The output side of the NAND device 26 is connected through the measurement target circuit 30 to the one input side of the NAND device 28, and also directly connected to the other input side of the NAND device 28. The output side of the NAND device 28 is connected to the output side of the chopper circuit 14. Due to such a configuration, a chop width Tw of the chopper circuit 14 is determined by the delay time of the measurement target circuit 30. Note that the measurement target circuit 30 is configured with inverting logic.

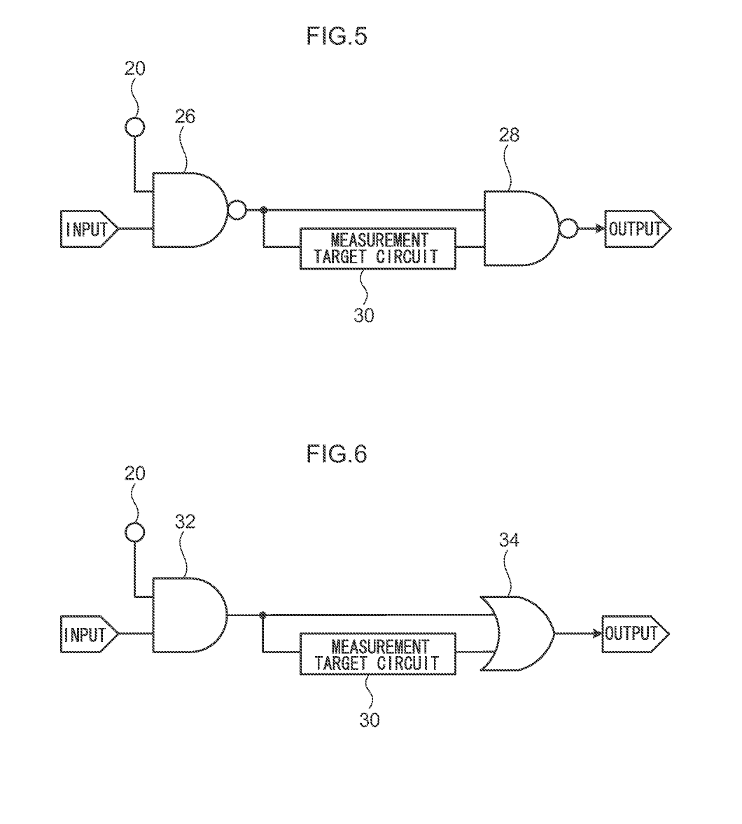

FIG. 6 illustrates another example of a configuration of the chopper circuit 14. The circuit example of FIG. 6, similarly to the circuit example in FIG. 5, is a chopper circuit that serves as a pulse output section operated by pulse fall. In the circuit example of FIG. 6, an AND device 32 replaces the NAND device 26 of the circuit example of FIG. 5, and an OR device 34 replaces the NAND device 28 therein.

The counter circuit 16 illustrated in FIG. 1 detects the rise or fall, or pulse width, of the input pulse, and counts the number of pulses, for example by integration. The counter circuit 16 has a detection threshold. Namely, the detection frequency is determined for detecting the rise or fall of a pulse, or pulse width. Thus any pulse that has been input with a frequency that exceeds a specific high frequency will not be counted. Obviously when the input of a pulse is finished, the counting is finished.

### Delay Time Measurement Processing

Explanation next follows regarding delay time measurement processing in the present exemplary embodiment.

First, in the semiconductor circuit delay measurement device 10, the chopper circuit 14 is provided within a loop of the delay circuit 12 that has a delay time difference between pulse rise and pulse fall. Were the chopper circuit 14 not to have been provided then loop operation would occur with a cycle of the delay time (Tup+Tdown).

Thus, the delay time difference between the pulse rise and pulse fall is adjusted in the direction such that the pulse width (chop width) of the pulse output from the chopper circuit 14 becomes narrower. The measurement target circuit 30 is employed as a delay generating portion that determines the pulse width (chop width) Tw of the pulse output from the chopper circuit 14 (see for example FIG. 5). The output of the chopper circuit 14 drives the counter circuit 16 that is external to the delay circuit 12. When this is performed, in cases in which there is no delay time difference in the delay circuit 12 (Tup=Tdown), the delay circuit 12 is continuously operated by a pulse having the pulse width (chop width) output from the chopper circuit 14.

However, in cases in which there is a delay time difference in the delay circuit 12 (Tdiff=|Tup−Tdown|>0), the pulse width (chop width) output from the chopper circuit 14 is successively reduced. Namely, the pulse width (chop width) output from the chopper circuit 14 is reduced each time of passing through the delay circuit 12. Thus when the pulse passes through the delay circuit 12 a number of times, the pulse ceases to be output from the delay circuit 12, and the pulse is eliminated. The counter circuit 16 is connected to the output of the chopper circuit 14, and the number of pulses is counted by the counter circuit 16.

The pulse width is accordingly reduced from the initial pulse width by the amount of delay time difference (Tdiff) each time the pulse passes through the delay circuit 12. It is possible to measure the initial chop width when the delay time difference (Tdiff) is known, namely acquired in advance. This initial chop width is a pulse width determined by the delay time of the measurement target circuit 30. This thereby enables the delay time Tw of the measurement target circuit 30 to be derived. Existing technology can be employed to measure delay times of the rise and fall of the pulse of the delay circuit 12, for example as in Japanese Patent Application Laid-Open (JP-A) No. 2007-235908. The delay times of the rise and fall of the pulse of the delay circuit 12 may be measured in advance.

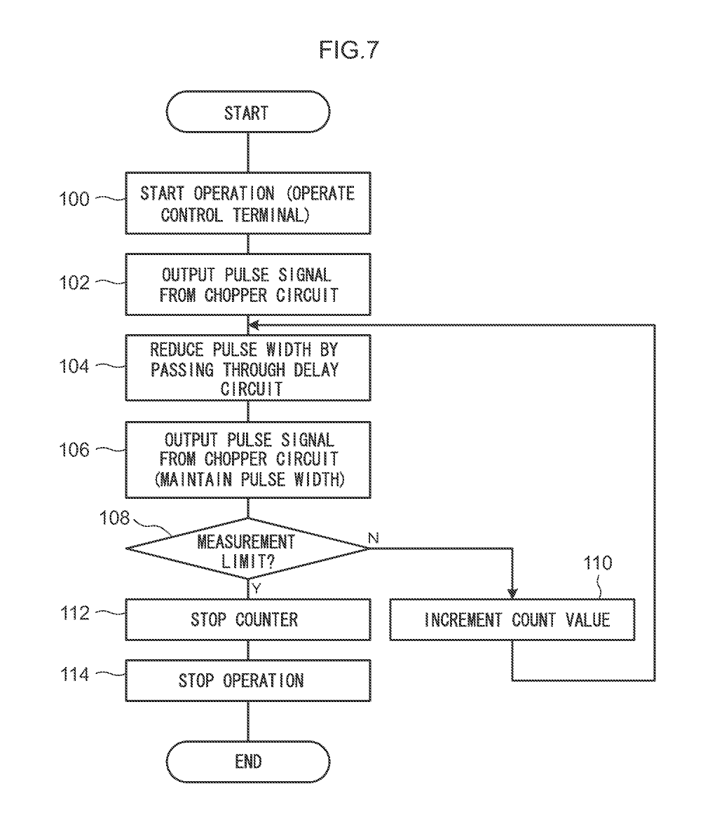

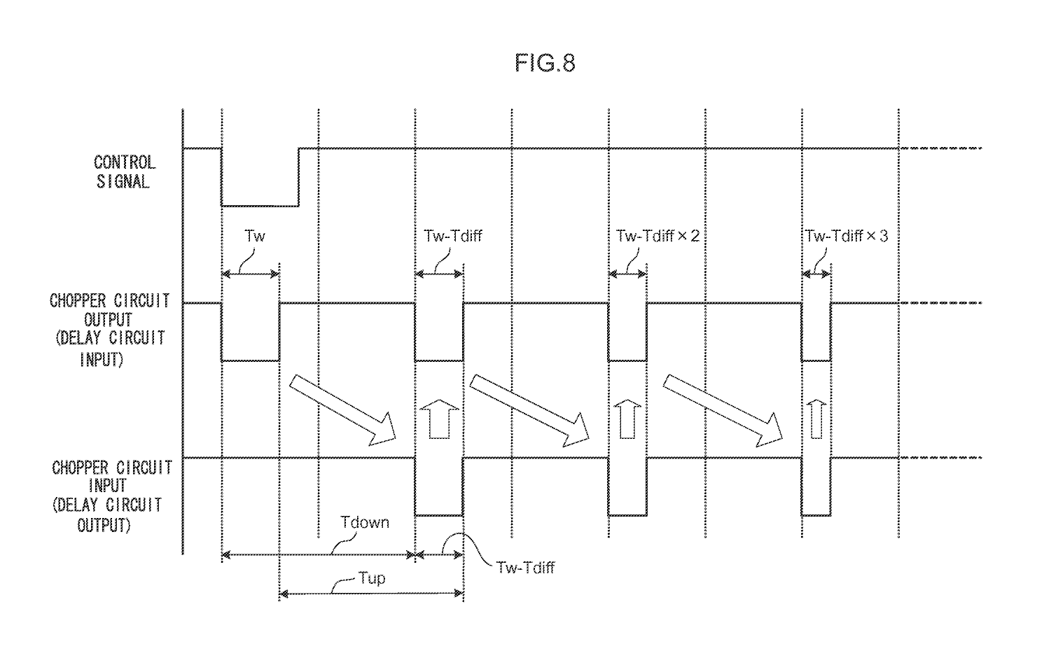

Detailed explanation next follows regarding delay time measurement processing, with reference to FIG. 7 and FIG. 8.

FIG. 7 illustrates a flow of delay time measurement employed in the semiconductor circuit delay measurement device 10. FIG. 8 illustrates a timing chart of the chopper circuit 14 of the semiconductor circuit delay measurement device 10. Note that in the present exemplary embodiment, the delay times are set such that Tw<Tup and Tw<Tdown.

First, prior to delay time measurement, the count value C (counter) of the counter circuit 16 is set to C=0 (reset). The control terminal 20 is operated to start delay time measurement processing, and operation is started (step 100 of FIG. 7). Namely, a control signal is input to the control terminal 20. The control signal only inputs a pulse at delay time measurement start (initial operation) (at the control signal on timing chart of FIG. 8).

Due to input of the control signal to the control terminal 20, a pulse is output from the chopper circuit 14 with a pulse width determined by the delay time of the measurement target circuit 30 (step 102). The pulse width of the pulse output from the chopper circuit 14 (initial chop width) is equivalent to the delay time Tw of the measurement target circuit 30. The pulse output from the chopper circuit 14 is input as it is to the delay circuit 12.

The delay circuit 12 has a delay time difference in the direction that reduces the pulse width of the pulse (Tdiff=|Tup−Tdown|>0). The pulse width is accordingly reduced by passing the pulse output from the chopper circuit 14 through the delay circuit 12 (step 104). The pulse output from the delay circuit 12 is chopped by the chopper circuit 14 and re-input to the delay circuit 12 (step 106). Namely, since a pulse of the delay time Tw or less is input to the chopper circuit 14, operation of the chopper circuit 14 ends prior to output of the pulse of the measurement target circuit 30, serving as the delay generating portion of the chopper circuit 14, arriving. Thus on operation of the chopper circuit 14 from the second time onwards, the input pulse thereto is output as it is.

The number of pulses is counted by the counter circuit 16 until the measurement limit is reached (until affirmative determination is made at step 108) of the counter circuit 16 connected to the output of the chopper circuit 14. Namely, in the counter circuit 16 the count value C is incremented one-by-one for each pulse output from the chopper circuit 14 up to the measurement limit (step 110). Counting in the counter circuit 16 is stopped when the pulse output from the chopper circuit 14 reaches the measurement limit pulse width T limit (step 112). Namely, the counter circuit 16 stops counting (step 112) when the counter circuit 16 has become the Tlimit<Tw−Tdiff·k (where k is a positive integer), and operation stops (step 114).

Thus, as illustrated in FIG. 8, the pulse width (chop width) of the pulse output from the chopper circuit 14 is reduced successively. The reason for this is that chop width Tw is only output the initial time, and from then onwards a pulse of delay time Tw or less is input. This means that operation of the chopper circuit 14 ends prior to arrival of the pulse output from the measurement target circuit 30 that serves as the delay generating portion of the chopper circuit 14. Each time of operation, the chop width is gradually reduced by the delay time difference Tdiff and output. Namely, the pulse that has been output from the chopper circuit 14 has its pulse width reduced each time it passes through the delay circuit 12. Thus after passing through the delay circuit 12 a number of times, the pulse is no longer output from the delay circuit 12, and the pulse is eliminated. Namely, the pulse width reduction time due to passing through the delay circuit 12 a number of times eventually matches or exceeds the delay time Tw of the measurement target circuit 30, and the pulse ceases to be output from the delay circuit 12. This thereby enables the delay time Tw to be derived from the count value C of the counter circuit 16 and the known delay time difference Tdiff.

From the above, the delay time Tw can be expressed by the following equation.

Tw=T·diff+C+Tlimit

Wherein: Tw is the delay time (the chop width of the chopper circuit 14) of the measurement target circuit 30; C is the count value when the counter circuit 16 is stopped (measurement result); Tdiff is the delay time difference (known) between the rise and fall of the pulse of the delay circuit 12; and Tlimit is the operation limit pulse width (known) of the counter circuit 16.

Note that in the above, the initial pulse is counted by the counter circuit 16. Namely, due to input of the control signal to the control terminal 20, a pulse of pulse width determined by the delay time of the measurement target circuit 30 is output from the chopper circuit 14. Thus configuration may accordingly be made such that this pulse is not counted. For example, “1” may be subtracted from the count value C of the counter circuit 16. Configuration may also be made such that the counter circuit 16 is reset by the first pulse of the chopper circuit.

Regarding setting of the delay time, the precision of delay time measurement can be raised by setting Tw<<Tdiff. The measurement intervals of the counter circuit 16 may also be made to be intervals of Tup+Tdown or longer. Subsequently, determination can be made that the counter circuit 16 has stopped operating in the case that the value of the counter circuit 16 stops changing.

It is accordingly possible to measure the delay time by inserting a given circuit (measurement target circuit) into the delay generating portion that determines the pulse width (chop width) output from the chopper circuit 14.

Moreover, according to the present exemplary embodiment, since it is sufficient simply to insert the measurement target circuit into the delay generating portion of the chopper circuit 14, there is no need for the measurement target circuit itself to be configured as a ring oscillator in order to measure the delay time. Note that although in the present exemplary embodiment configuration is made such that the measurement target circuit is inserted into the delay generating portion in the chopper circuit 14, there is no need for the chopper circuit 14 to have the measurement target circuit as a configuration element. Thus configuration may be made such that the measurement target circuit is connected to the chopper circuit 14 from outside.

Moreover, according to the present exemplary embodiment, configuration may be made with delay circuits made from inverters alone to substitute for a ring oscillator, thereby enabling the circuit scale to be reduced. It thereby becomes possible to greatly reduce the circuit overall when there is a large scale measurement target circuit. A simple comparison will now be made of the number of transistors, considering an inverter made from two transistors. In such cases, the number of transistors of the measurement target circuit is denoted A, the number of stages in a ring oscillator is denoted n, and the difference in the number of transistors employed in the other control circuits is denoted D. Doing so shows a reduction effect in the number of transistors by the amount expresses by the following equation in comparison to an existing example of a ring oscillator.

A·n−(A+2·n)·D

Moreover, according to the present exemplary embodiment, since it is sufficient simply to insert the measurement target circuit into the delay generating portion of the chopper circuit 14, the actual delay time of the measurement target circuit can be measured, rather than just an average value. Namely, there is no need to derive the average delay time from delay times measured by connecting plural stages of measurement target circuits together in series.

Note that when the semiconductor circuit delay measurement device 10 is provided connected directly to a semiconductor circuit, such as onto a substrate, the count value C of the counter circuit 16 may be acquired by a configuration in which the counter circuit 16 includes a display for displaying the count value. The delay time Tw can then be derived from the count value C and the known delay time difference Tdiff. The count value C of the counter circuit 16 may also be acquired externally by a configuration in which the counter circuit 16 includes an interface that outputs the count value. Acquisition of the count value C may be achieved by simply reading a signal, and there is no need for the frequency of the signal to be a high frequency. This thereby enables the delay time Tw to be simply derived externally from the acquired count value C and the known delay time difference Tdiff.

### Second Exemplary Embodiment

Explanation next follows regarding a second exemplary embodiment. The present exemplary embodiment is configured substantially the same as the above exemplary embodiment, hence the same reference numerals are appended to similar portions, and detailed explanation thereof is omitted.

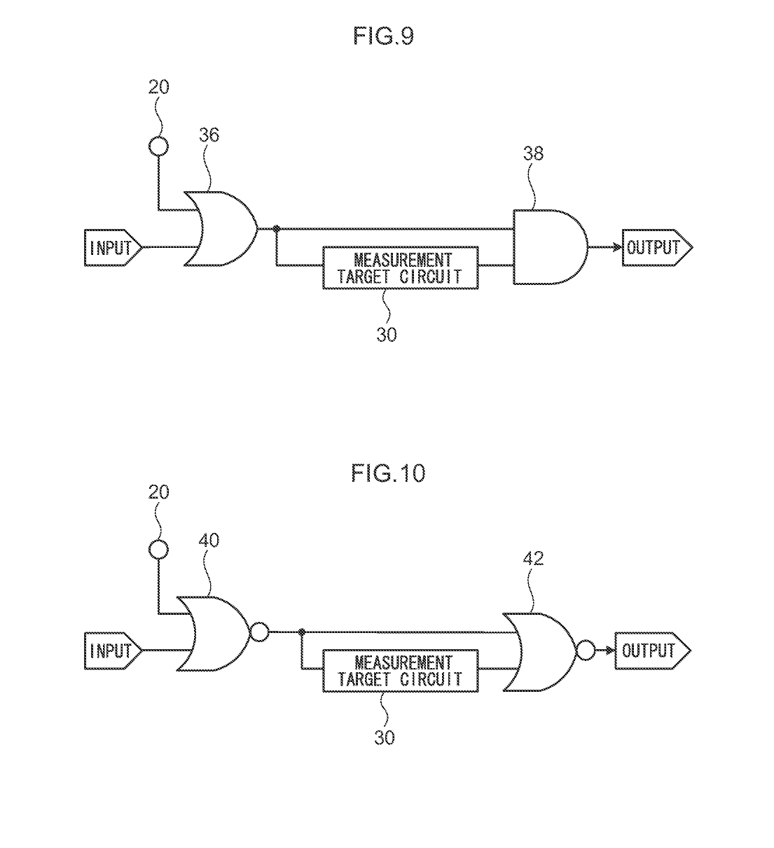

FIG. 9 illustrates an example of a configuration of a chopper circuit 14 according to the present exemplary embodiment. The example in FIG. 9 illustrates a chopper circuit serving as a pulse output section that operates by pulse rise. The chopper circuit 14 is configured by a chopper with chop width determined according to a delay time of the measurement target circuit 30. The chopper circuit 14 is configured by an OR device 36, an AND device 38, and a measurement target circuit 30. The input side of the chopper circuit 14 is connected to one input side of the OR device 36, and a control terminal 20 is connected to the other input side thereof. The output side of the OR device 36 is connected through the measurement target circuit 30 to one input side of the AND device 38, and is also directly connected to the other input side of the AND device 38. The output side of the AND device 38 is connected to the output side of the chopper circuit 14. Due to this configuration, a chop width Tw of the chopper circuit 14 is determined by the delay time of measurement target circuit 30.

FIG. 10 illustrates another example of a configuration of the chopper circuit 14 according to the present exemplary embodiment. The circuit example in FIG. 10 is, similarly to the circuit example in FIG. 9, a chopper circuit serving as a pulse output section that operates by pulse rise. The circuit example of FIG. 10 has a NOR device 40 substituted for the OR device 36 in the circuit example of FIG. 9, and a NOR device 42 substituted for the OR device 36 therein.

### Delay Time Measurement Processing

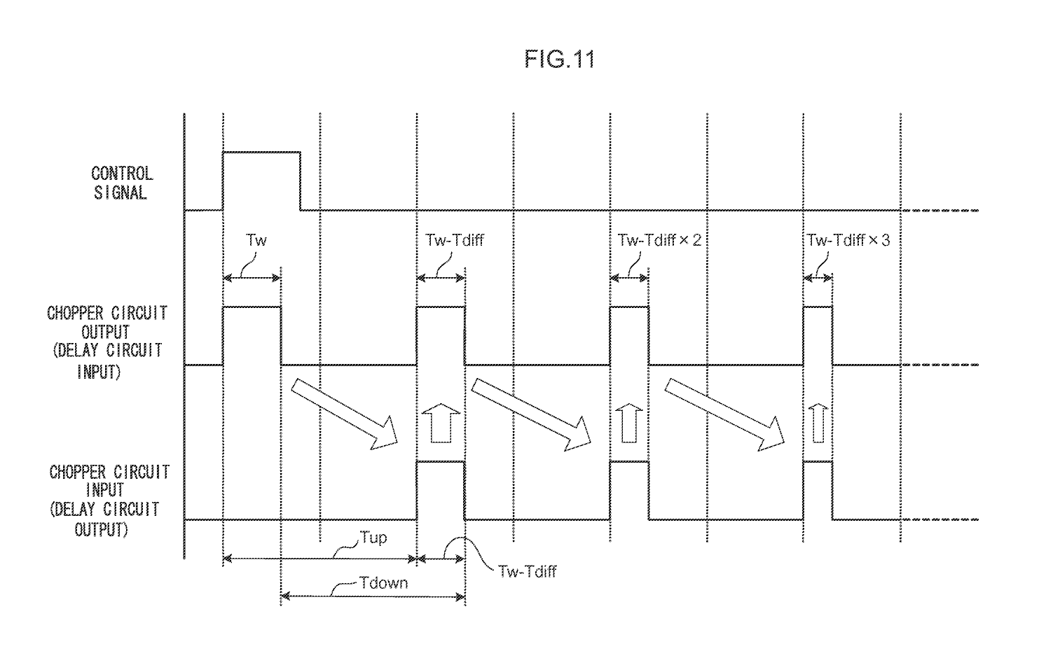

Explanation next follows regarding delay time measurement processing in the present exemplary embodiment. Note that a difference of the present exemplary embodiment to the first exemplary embodiment is the signal logic. Detailed explanation follows regarding the delay time measurement processing according to the present exemplary embodiment, with reference to FIG. 11.

FIG. 11 illustrates a timing chart of the chopper circuit 14 of the semiconductor circuit delay measurement device 10.

First, prior to delay time measurement, a count value C (counter) of the counter circuit 16 is reset, and the control terminal 20 is operated to start operation. Namely, a control signal is input to the control terminal 20. The control signal is a positive logic signal, as illustrated in FIG. 11.

Due to input of the control signal to the control terminal 20, a pulse is output from the chopper circuit 14 to the delay circuit 12, with a pulse width Tw determined by the delay time of the measurement target circuit 30. The delay circuit 12 has a delay time difference Tdiff in the direction that reduces the pulse width of the pulse. The pulse width is accordingly reduced by passing the pulse output from the chopper circuit 14 through the delay circuit 12. The pulse output from the delay circuit 12 is chopped by the chopper circuit 14 and then re-input to the delay circuit 12.

The number of pulses is counted by the counter circuit 16 until the measurement limit of the counter circuit 16 connected to output of the chopper circuit 14 is reached. Namely, counting in the counter circuit 16 stops when the pulse output from the chopper circuit 14 reaches the measurement limit pulse width T limit (Tlimit<Tw−Tdiff·k).

Thus, the pulse width (chop width) of the pulse output from the chopper circuit 14 is reduced, and after passing through the delay circuit 12 a number of times, the pulse is eliminated, and the count of the counter circuit 16 stops. The delay time Tw can be derived from the count value C of the counter circuit 16 and the known delay time difference Tdiff.

### Third Exemplary Embodiment

Explanation next follows regarding a third exemplary embodiment. The present exemplary embodiment is configured substantially the same as the first exemplary embodiment, hence the same reference numerals are appended to similar portions, and detailed explanation thereof is omitted.

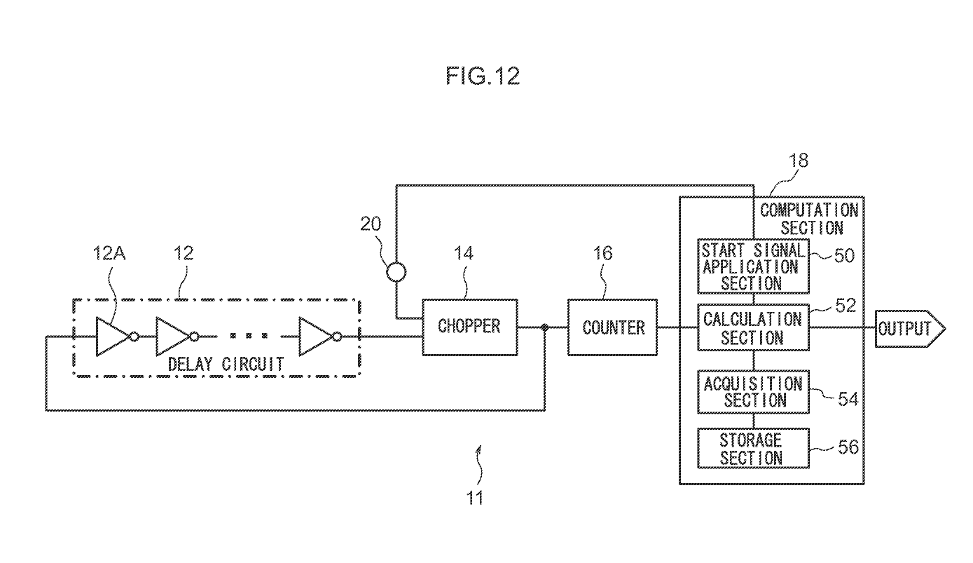

FIG. 12 illustrates a schematic configuration of a delay measurement device 11, serving as an example of an electronic circuit delay measurement device according to the present exemplary embodiment. The delay measurement device 11 according to the present exemplary embodiment includes a computation section 18, in addition to the configuration of the semiconductor circuit delay measurement device 10. The output side of the counter circuit 16 is connected to the input side of the computation section 18 contained in the semiconductor circuit delay measurement device 10. The control side of the computation section 18 is connected to the control terminal 20.

The computation section 18 is configured to control delay time measurement processing and to derive and output the delay time of a measurement target circuit 30. The computation section 18 is capable of, similarly to the semiconductor circuit delay measurement device 10, being directly mounted on a semiconductor circuit such as a substrate.

The computation section 18 is equipped with a calculation section 52 that has the role of calculating and controlling the delay time of the measurement target circuit 30. The computation section 18 is also equipped with a start signal application section 50 that applies a delay time measurement start signal to the control terminal 20. The start signal application section 50 is configured so as to output the start signal under instruction from the calculation section 52. Moreover, the computation section 18 is equipped with an acquisition section 54 for acquiring a pulse width reduction time in the delay circuit 12. The reduction time output by the acquisition section 54 corresponds to the delay time difference (Tdiff) by which the pulse width is reduced each time the pulse passes through the delay circuit 12. The acquisition section 54 is connected to the calculation section 52 such that the acquired reduction time (delay time difference Tdiff) is input thereto.

Note that in the present exemplary embodiment the computation section 18 is equipped with a storage section 56. Explanation next follows regarding storing the reduction time (delay time difference Tdiff) in the storage section 56. Configuration may be made such that an input section may be substituted for the storage section 56, so as to input the reduction time for the pulse width of the delay circuit 12.

The calculation section 52 is connected to the output side of the counter circuit 16. Connection is made to the calculation section 52 such that the signal output from the counter circuit 16 is input thereto. The calculation section 52 may be connected so as to reference the count value of the counter circuit 16. The calculation section 52 is configured to output the calculation result as a signal. The output signal of the calculation section 52 enables a completion signal indicating that measurement is complete, and the measurement completed delay time to be output. Note that when the calculation section 52 includes configuration enabling confirmation of the measurement completed delay time, it is sufficient for the output signal of the calculation section 52 to include just a completion signal output when the delay time measurement was completed. As an example of the calculation section 52 configured to enable confirmation of delay time at measurement completion is display device for displaying the delay time.

In the present exemplary embodiment, the calculation section 52 of the computation section 18 is configured including a CPU and memory, such as RAM. A delay measurement processing program, described in detail later, is stored in the memory. The calculation section 52 includes an interface for connection to the counter circuit 16, and the start signal application section 50 includes an interface for connecting to the control terminal 20. Note that the computation section 18 may be connected to a display, that is a display device serving as an example of an output display, and may be connected to a keyboard and mouse, serving as an input section.

Note that the computation section 18 may be configured as described above directly mounted on a semiconductor circuit, such as a substrate, or configured by an independent device.

### Delay Time Measurement Processing

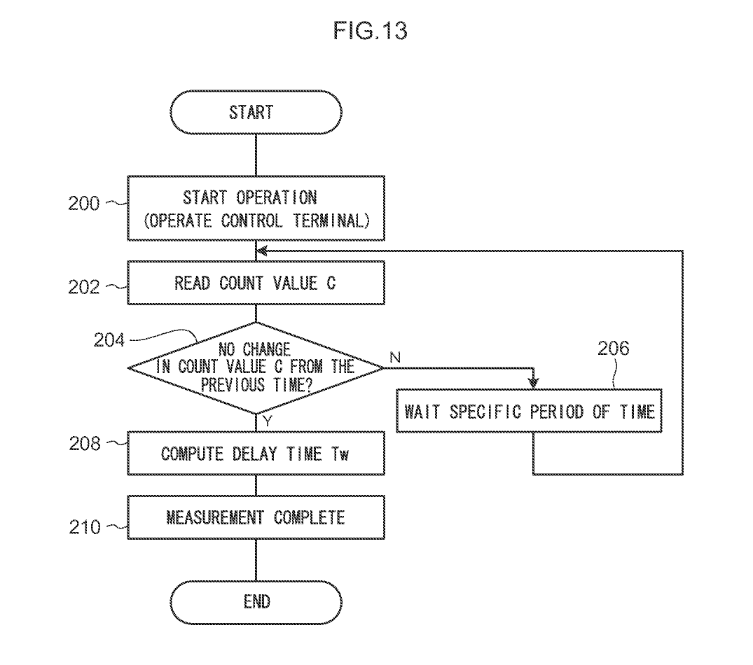

Explanation next follows regarding delay time measurement processing in the present exemplary embodiment. FIG. 13 illustrates a flow chart of flow in delay time measurement processing executed by the calculation section 52 of the computation section 18.

First, when the delay time measurement processing has been started, the processing routine of FIG. 13 is executed, and prior to delay time measurement, the count value C (counter) of the counter circuit 16 is set to C=0 (reset), and processing proceeds to step 200. At step 200, to operate the control terminal 20 to start operation, an instruction signal to input the control signal to the control terminal 20 is output to the start signal application section 50.

Due to input of the control signal to the control terminal 20 as described above, a pulse is output from the chopper circuit 14 with a pulse width determined by the delay time of the measurement target circuit 30. The chopper circuit 14 outputs to the delay circuit 12 the pulse of pulse width (initial chop width: equivalent to the delay time Tw of the measurement target circuit 30). The delay circuit 12 reduces the pulse width of the pulse by the amount of the delay time difference (Tdiff). The pulse output from the delay circuit 12 is chopped by the chopper circuit 14 and re-input to the delay circuit 12. These pulses are counted (count value C) by the counter circuit 16 until the measurement limit is reached. Counting in the counter circuit 16 is stopped when the pulse output from the chopper circuit 14 reaches the measurement limit pulse width Tlimit.

The calculation section 52 of the computation section 18 then proceeds to step 202, and reads the count value C counted by the counter circuit 16. Then at step 204, determination is made as to whether or not the count value C read at step 202 has changed from the count value C the previous time. At step 204, determination is made as to whether or not the count value C has increased. When negative determination is made at step 204, after waiting for a specific period of time at step 206, processing then returns to step 202. The specific period of time at step 206 is set as a period of time longer than the cycle of the ring shape-configured delay circuit 12. This thereby enables determination to be made when there is no longer an increase in count value C that either the pulse output from the chopper circuit 14 has been eliminated, or that the pulse has reached the measurement limit of the counter circuit 16.

At the next step 208, the calculation section 52 computes the delay time Tw. First the count value C of the counter circuit 16 and the pulse width Tlimit of the measurement limit is acquired. Then the delay time difference Tdiff of the delay circuit 12 is acquired. Then the delay time Tw is computed according to the above equation (Tw=Tdiff·C+Tlimit). Then at step 210, the calculation section 52 outputs the calculation result as a signal. Namely, the calculation section 52 outputs a completion signal indicating that measurement has been completed, and outputs a signal indicating the delay time when measurement was completed.

Thus, according to the present exemplary embodiment, provision of the calculation section enables delay time of the measurement target circuit to be derived simply.

Moreover, configuring the calculation section independently enables simplification of circuit incorporation into the semiconductor circuit, thereby enabling device configuration to be simply.

Note that obviously the present exemplary embodiment is also applicable to the second exemplary embodiment.

### Fourth Exemplary Embodiment

Explanation next follows regarding a fourth exemplary embodiment. The present exemplary embodiment is configured substantially the same as the above exemplary embodiments, hence the same reference numerals are appended to similar portions, and detailed explanation thereof is omitted.

The present exemplary embodiment derives the delay times Tw of plural measurement target circuits.

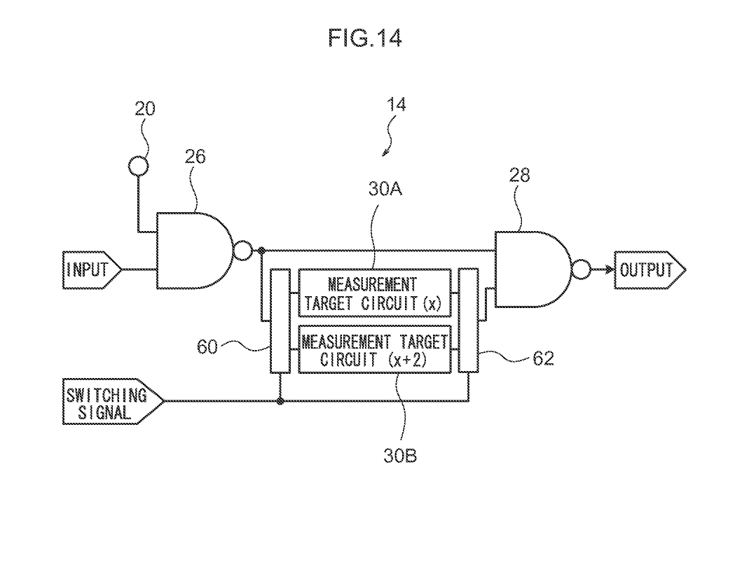

FIG. 14 illustrates an example of a configuration of the chopper circuit 14 according to the present exemplary embodiment. The example of FIG. 14 illustrates a chopper circuit serving as a pulse output section that operates by fall of a pulse. The chopper circuit 14 is configured from NAND devices 26 and 28, and a measurement target circuit 30 that contains a measurement target circuit 30A and a measurement target circuit 30B. The output side of the NAND device 26 is connected to an input side switch section 60. An output side switch section 62 is also connected to one input side of the NAND device 28. The measurement target circuit 30A and the measurement target circuit 30B are connected to the input side switch section 60 and the output side switch section 62. Connection is made such that a switching signal is input to the control side of each of the input side switch section 60 and the output side switch section 62.

The switching signal may be output from the calculation section 52 described above, or may be input independently. The connections of the measurement target circuit 30A and the measurement target circuit 30B are switched by input of the switching signal. Namely, on instruction of the measurement target circuit 30A by the switching signal, the output side of the NAND device 26 is connected through the measurement target circuit 30A to one input side of the NAND device 28. However, on instruction of the measurement target circuit 30B by the switching signal, the output side of the NAND device 26 is connected through the measurement target circuit 30B to one input side of the NAND device 28.

Note that the example of FIG. 14 illustrates the measurement target circuit 30 including two circuits, the measurement target circuit 30A and the measurement target circuit 30B, however configuration may be made with 3 or more measurement target circuits. Moreover, although the example of FIG. 14 has been explained in a case in which the input side switch section 60 is provided, the input side switch section 60 is not necessarily provided, and the output side of the NAND device 26 may be connected commonly to the respective input sides of the measurement target circuit 30A and the measurement target circuit 30B.

### Delay Time Measurement Processing

Explanation next follows regarding delay time measurement processing in the present exemplary embodiment.

First in the present exemplary embodiment, prior to delay time measurement, a switching signal to measure the measurement target circuit 30A, or to measure the measurement target circuit 30B, is output. Consider here a case in which the switching signal to measure the delay time of the measurement target circuit 30A is output. Next, the count value C of the counter circuit 16 is reset, and the control terminal 20 is operated and operation started. Namely, due to input of the control signal to the control terminal 20, a pulse of pulse width determined by the delay time of the measurement target circuit 30A is output from the chopper circuit 14. The chopper circuit 14 outputs the pulse equivalent to the delay time Tw of the measurement target circuit 30A to the delay circuit 12.

The delay circuit 12 reduces the pulse width of the pulse by the delay time difference (Tdiff). The pulse output from the delay circuit 12 is chopped by the chopper circuit 14 and re-input to the delay circuit 12. The counter circuit 16 counts these pulses (count value C) until the measurement limit. The counter circuit 16 stops counting when the pulses output from the chopper circuit 14 reach the measurement limit pulse width Tlimit. This count value is a count value CA of the measurement target circuit 30A. The switching signal for measuring the delay time of the measurement target circuit 30B is similarly output, and a count value CB of the counter circuit 16 is obtained.

This thereby enables the delay times Tw of each of the measurement target circuit 30A and the measurement target circuit 30B to be obtained.

In this manner it is thereby possible to measure delay time for plural measurement target circuits by selectably inserting plural measurement target circuits into a delay generating portion that determines the pulse width (chop width) output from the chopper circuit 14. Thus by switching which measurement target circuit out of the plural measurement target circuits is connected, the delay time of multiple circuits can be measured with a small surface area.

Explanation next follows regarding a case in which the present exemplary embodiment derives and utilizes the delay time Tw of plural measurement target circuits to derive the pulse width Tlimit of the measurement limit in the counter circuit 16.

As a configuration in the counter circuit 16 to derive the measurement limit pulse width Tlimit, the measurement target circuit 30A is set as a circuit with x stages of inverters (wherein x is a positive integer). The measurement target circuit 30B is set as a circuit with (x+2) stages of inverters.

Then, similarly to as described above, the delay times Tw are derived for each of the measurement target circuit 30A and the measurement target circuit 30B. The difference between the count values CA, CB when this is performed is equivalent to the delay time of a two stages worth of an inverter. This thereby enables the delay time Twx of an x-stage inverter to be derived. The difference between the delay time Twx of such an x-stage inverter, and the deray time Tw of the measurement target circuit 30A (=Tdoff·C) that has x-stages of inverter, is then derived. The difference value is equivalent to the pulse width Tlimit of the measurement limit in the counter circuit 16.

This thereby enables the pulse width of the measurement limit in the counter circuit 16 to be derived.

### Fifth Exemplary Embodiment

Explanation next follows regarding a fifth exemplary embodiment. The present exemplary embodiment has substantially the same configuration to that of the above exemplary embodiments, and so the same reference numerals are appended thereto, and detailed explanation is omitted thereof.

In the first exemplary embodiment, explanation was given regarding the chopper circuit 14 for a case of in which a control signal is input to the input side of the measurement target circuit 30. In the present exemplary embodiment, as a modified example, explanation follows regarding the chopper circuit 14 in a case in which a control signal is input to the output side of the measurement target circuit 30.

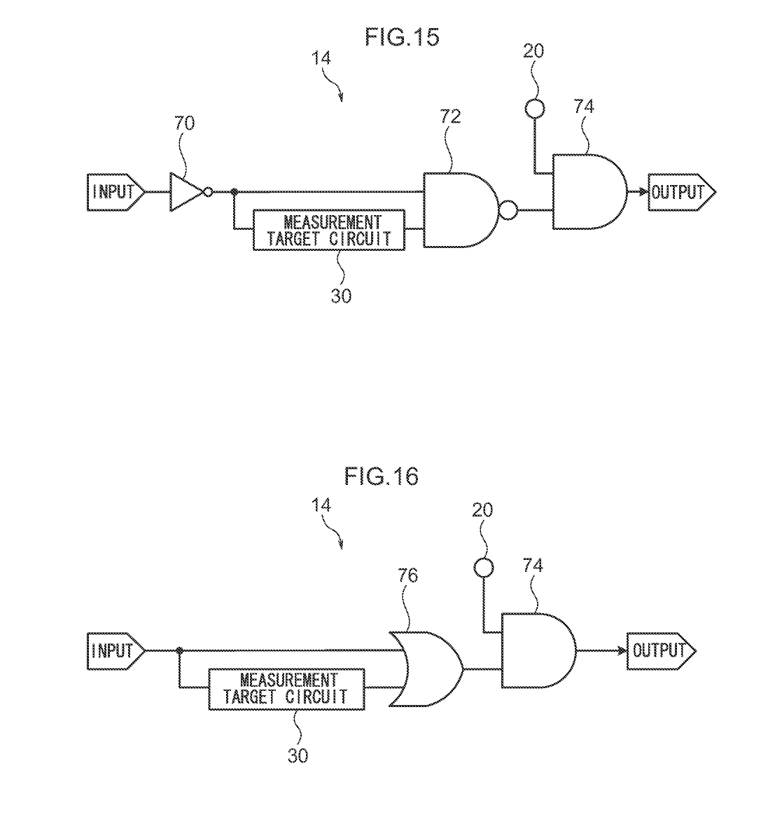

FIG. 15 illustrates an example of a configuration of a chopper circuit 14 according to the present exemplary embodiment. The example in FIG. 15 illustrates a chopper circuit serving as a pulse output section that is operated by fall of a pulse. The chopper circuit 14 is configured including an inverter 70, a NAND device 72, an AND device 74, and a measurement target circuit 30. The input side of the chopper circuit 14 is connected to input side of the inverter 70. The output side of the inverter 70 is connected through the measurement target circuit 30 to one input side of the NAND device 72, and also to the other input side of the NAND device 72. The other input side of the NAND device 72 is connected to one output side of the control terminal 20. The other input side of the AND device 74 is connected to the output side of the chopper circuit 14. Due to such configuration, the delay time Tw of the chopper circuit 14 is determined by the delay time of the measurement target circuit 30.

FIG. 16 illustrates an example of another configuration of the chopper circuit 14 according to the present exemplary embodiment. The circuit example in FIG. 16 is, similarly to the circuit example of FIG. 15, a chopper circuit serving as a pulse output section that is operated by fall of a pulse. The circuit example of FIG. 16 has an OR device 76 substituted for the NAND device 72 in the circuit example of FIG. 15, and an inverter 70 has been made conducting.

### Delay Time Measurement Processing

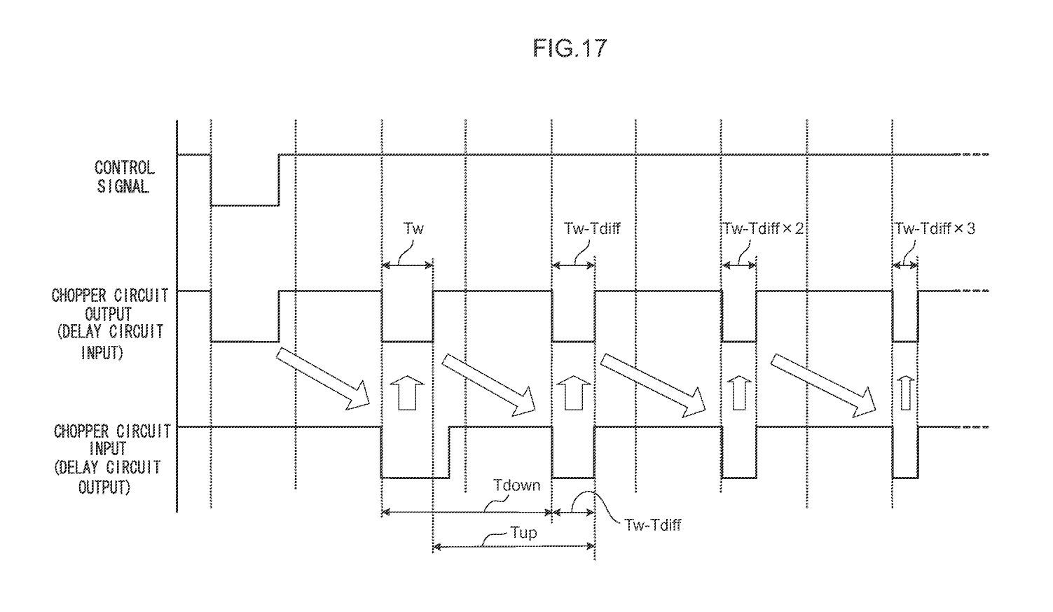

Explanation next follows regarding delay time measurement processing in the present exemplary embodiment, with reference to FIG. 17.

FIG. 17 illustrates a timing chart of the chopper circuit 14 according to the present exemplary embodiment.

First, prior to delay time measurement, the count value C (counter) of the counter circuit 16 is reset. To start delay time measurement processing, the control terminal 20 is operated and operation is started. Namely, a control signal is input to the control terminal 20. The control signal only inputs a pulse at delay time measurement start (on initial operation). Due to input of the control signal to the control terminal 20, the AND device 74 of the chopper circuit 14 outputs a pulse as it is. The pulse output from the chopper circuit 14 is input to the delay circuit 12, the pulse width is reduced by the amount of the delay time difference (Tdiff), and then input to the chopper circuit 14. Note that the pulse width (>>Tw+Tdiff) of the control signal is set to be significantly greater than the delay time difference. Then the pulse of pulse width determined by the delay time of the measurement target circuit 30 is output from the chopper circuit 14 (equivalent to the delay time Tw of the measurement target circuit 30). The pulse output from the chopper circuit 14 is input to the delay circuit 12.

Then, the pulse width is reduced due to the pulse output from the chopper circuit 14 passing through the delay circuit 12. The pulse output from the delay circuit 12 is chopped by the chopper circuit 14 and re-input to the delay circuit 12. Then the number of pulses is counted by the counter circuit 16 until the measurement limit of the counter circuit 16 connected to the output of the chopper circuit 14 is reached. In the case that the pulse output from the chopper circuit 14 has reached the measurement limit pulse width Tlimit, the counter circuit 16 stops counting.

Thus, as illustrated in FIG. 17, the pulse width (chop width) of the pulse output from the chopper circuit 14 is reduced successively. After the control signal pulse has been output here, the pulse of chop width Tw is then output only the initial time, and from then onwards a pulse of delay time Tw or less is input. Thus chop width is reduced at each operation by the amount of the delay time difference Tdiff, and output. The pulse stops being output from the delay circuit 12 when the reduction time due to passing through the delay circuit 12 a number of times has matched or exceeded the delay time Tw of the measurement target circuit 30. It is accordingly possible to derive the delay time Tw from the count value C of the counter circuit 16 and the known delay time difference Tdiff.

Note that in the above, the control signal pulse and the delayed initial time pulse are counted with the counter circuit 16. Configuration is accordingly made so as not to count these pulses. For example, “2” is subtracted from the count value C of the counter circuit 16. Moreover, configuration may be made such that the counter circuit 16 is reset by the first pulse of the delay circuit.

### Sixth Exemplary Embodiment

Explanation next follows regarding a sixth exemplary embodiment. The present exemplary embodiment is configured substantially the same as the above exemplary embodiments and so the same reference numerals are appended to similar parts, and detailed explanation is omitted thereof.

In the second exemplary embodiment, explanation has been given regarding the chopper circuit 14 in a case in which the control signal is input at the input side of the measurement target circuit 30. In the present exemplary embodiment, as a modified example, explanation follows regarding a chopper circuit 14 for a case in which the control signal is input to the output side of the measurement target circuit 30.

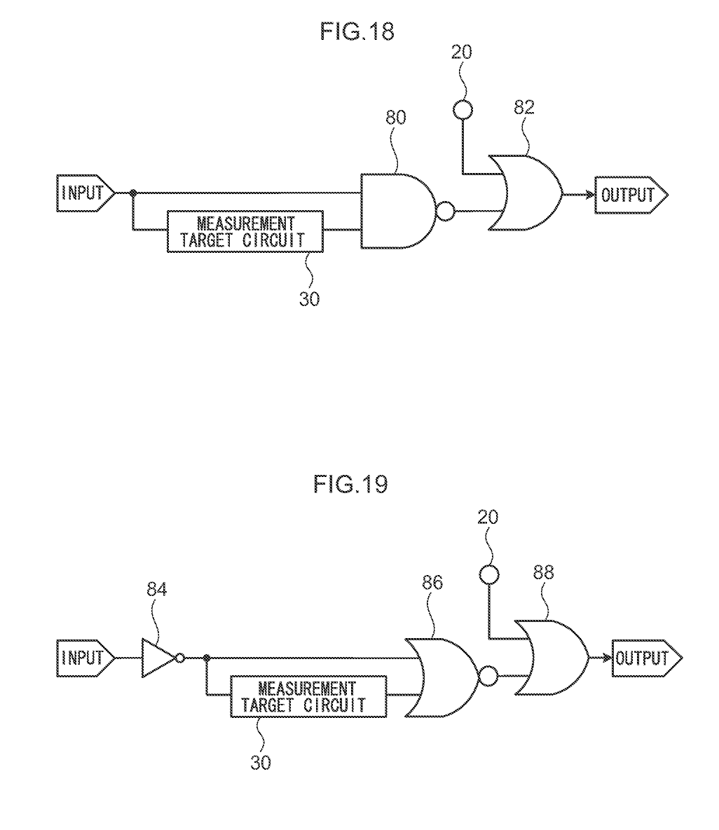

FIG. 18 illustrates an example of a configuration of the chopper circuit 14 in the present exemplary embodiment. The example of FIG. 18 illustrates a chopper circuit serving as a pulse output section that is operated by rise of a pulse. The chopper circuit 14 is configured from an OR device 82, a NAND device 80, and measurement target circuit 30. The input side of the chopper circuit 14 is connected through the measurement target circuit 30 to one input side of the NAND device 80, and also connected to the other input side of the NAND device 80. The output side of the NAND device 80 is connected to one input side of the OR device 82, and the control terminal 20 is connected to the other input side of the OR device 82. The output side of the OR device 82 is connected to the output side of the chopper circuit 14. Due to such a configuration, the chop width Tw of the chopper circuit 14 is determined by the delay time of the measurement target circuit 30.

FIG. 19 illustrates an example of another configuration of the chopper circuit 14 according to the present exemplary embodiment. The circuit example in FIG. 19 is, similarly to the circuit example in FIG. 18, a chopper circuit serving as a pulse output section that operates by a pulse rise. The circuit example of FIG. 19 has a NOR device 86 substituted for the NAND device 80 in the circuit example of FIG. 18, and an inverter 84 is also added to the input side of the chopper circuit 14.

### Delay Time Measurement Processing

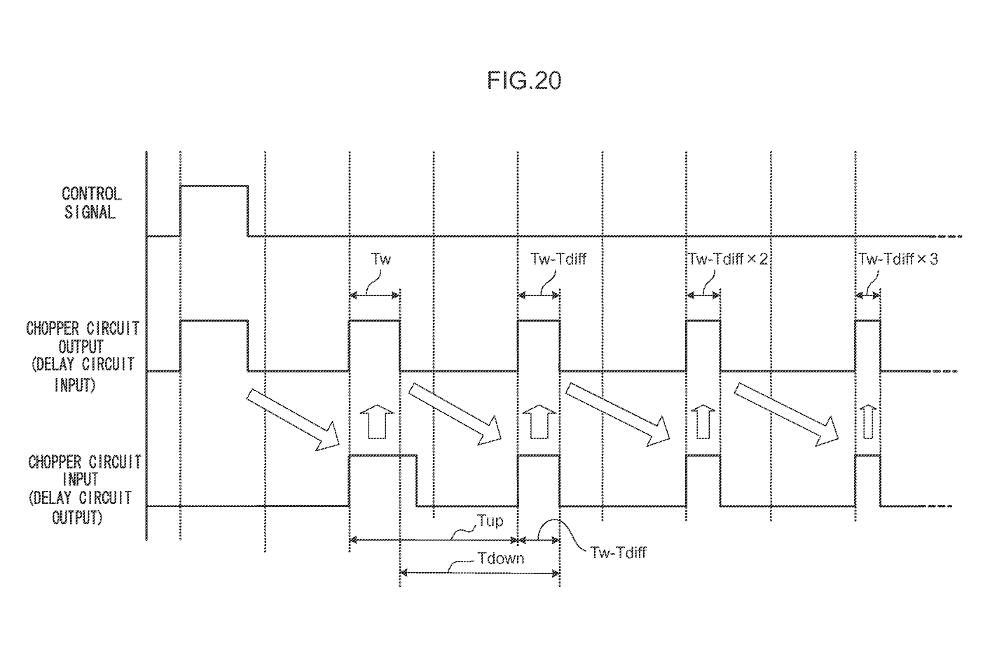

FIG. 20 illustrates a timing chart in the chopper circuit 14 of the semiconductor circuit delay measurement device 10.

First, prior to delay time measurement, the count value C (counter) of the counter circuit 16 is reset, and the control terminal 20 operated to start operation. Namely, the control signal is input to the control terminal 20. This control signal is a positive logic signal as illustrated in FIG. 20.

Due to input of the control signal to the control terminal 20, the OR device 82 of the chopper circuit 14 outputs a pulse as it is. The pulse output from the chopper circuit 14 is input to the delay circuit 12, and the pulse width is reduced by the amount of the delay time difference (Tdiff), and input to the chopper circuit 14. Note that the pulse width (>>Tw+Tdiff) of the control signal is set to be significantly greater than the delay time difference. The pulse of pulse width determined by the delay time of the measurement target circuit 30 is then output from the chopper circuit 14 (equivalent to the delay time Tw of the measurement target circuit 30). The pulse output from the chopper circuit 14 is input to the delay circuit 12.

Then, the pulse width is reduced due to the pulse output from the chopper circuit 14 passing through the delay circuit 12. The pulse output from the delay circuit 12 is chopped by the chopper circuit 14 and re-input to the delay circuit 12. Then the number of pulses are counted by the counter circuit 16 until the measurement limit of the counter circuit 16 connected to the output of the chopper circuit 14 is reached. When the pulse output from the chopper circuit 14 has reached the measurement limit pulse width Tlimit, the counter circuit 16 stops counting.

Thus, as illustrated in FIG. 20, the pulse width (chop width) of the pulse output from the chopper circuit 14 is reduced successively. The pulse then stops being output from the delay circuit 12. It is accordingly possible to derive the delay time Tw from the count value C of the counter circuit 16 and the known delay time difference Tdiff.

Note that in the above, the control signal pulse and the delayed initial time pulse are counted with the counter circuit 16. Configuration is accordingly made so as not to count these pulses. For example, “2” is subtracted from the count value C of the counter circuit 16. Moreover, configuration may be made such that the counter circuit 16 is reset by the first pulse of the delay circuit.

Note that explanation has been given above of a semiconductor circuit delay measurement device for an example of a system with an example of a delay measurement device electronic circuit. However, there is no limitation to such a configuration, and obviously various improvement and modifications may be made within a scope not departing from the spirit explained above.

Moreover, although explanation has been given above of a semiconductor circuit as an example of an electronic circuit that is the delay time measurement target, there is no limitation thereto, and the technology disclosed herein is applicable to measurement of delay times of various electronic circuits other than semiconductor circuits.

Moreover, although explanation has been given above of an embodiment in which a program is stored on a storage section, a processing program may be provided in a format recorded on a recording medium, such as a CD-ROM or DVD-ROM.

An aspect is capable of suppressing the scale of circuit to measure the delay time of a particular area electronic circuit, such as a semiconductor circuit.

All cited documents, patent applications and technical standards mentioned in the present specification are incorporated by reference in the present specification to the same extent as if the individual cited document, patent application, or technical standard was specifically and individually indicated to be incorporated by reference.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic circuit delay measurement device, comprising:
a delay section configured by a loop that reduces a pulse width of an input pulse by a specific reduction time and outputs the pulse, and that is connected such that the output pulse is employed as input;
a pulse output section that is provided in the delay section loop, and that outputs a pulse of pulse width determined according to a delay time of an electronic circuit of a delay time measurement target when provided with a signal for starting a delay measurement, and that, for a pulse that has been input, outputs a pulse of pulse width determined according to the delay time of the electronic circuit; and
a counting section that counts a pulse number of pulses output from the pulse output section.

2. The electronic circuit delay measurement device of claim 1, further comprising a computation section that computes the delay time of the electronic circuit from a count value counted by the counting section until no more pulses are forthcoming from the pulse output section and from the pulse width reduction time.

3. The electronic circuit delay measurement device of claim 2, wherein the computation section comprises:
an acquisition section that acquires a specific reduction time of the delay section;
a calculation section that calculates the electronic circuit delay time based on the count value of the counting section and the specific reduction time of the delay section acquired by the acquisition section; and
a start signal application section that provides a signal for starting delay measurement.

4. The electronic circuit delay measurement device of claim 3, wherein the calculation section includes a determination section that reads count values of the counting section at respective fixed intervals and determines that a state exists in which no more pulses are forthcoming from the pulse output section when the read count values become the same count value.

5. The electronic circuit delay measurement device of claim 1, wherein the pulse output section comprises:
a gate portion that outputs a drive signal when provided with a signal for starting a delay measurement or with an input signal; and
a logic portion that outputs a pulse of pulse width according to the electronic circuit delay time when input with the drive signal and with the drive signal that has passed through the electronic circuit.

6. The electronic circuit delay measurement device of claim 1, wherein the pulse output section comprises:
a logic portion that is input with an input signal and with the input signal that has passed through the electronic circuit, and that outputs a signal of pulse width according to the electronic circuit delay time; and
a gate portion that outputs a pulse when provided with a signal for starting a delay measurement or with the signal from the logic portion.

7. The electronic circuit delay measurement device of claim 1, wherein the delay section includes an N-channel transistor and a P-channel transistor having different conductance to each other.

8. The electronic circuit delay measurement device of claim 1, wherein:
the delay section comprises a basic transistor set including an N-channel transistor and a P-channel transistor, and at least one expansion transistor set including a plurality of sets of the basic transistor set connected together in parallel such that each of the N-channel transistors and the P-channel transistors is selectable; and
the delay time is adjusted by selecting N-channel transistor(s) or P-channel transistor(s) of the expansion transistor set.

9. The electronic circuit delay measurement device of claim 1, wherein the counting section is input with a pulse that has passed through a signal path branched from an output portion of the pulse output section, and outputs a count signal according to the count value of counted pulses that have been output from the pulse output section.

10. An electronic circuit delay measurement method employed for an electronic circuit delay measurement device comprising:
a delay section configured by a loop that reduces a pulse width of an input pulse by a specific reduction time and outputs the pulse, and that is connected such that the output pulse is employed as input;
a pulse output section that is provided in the delay section loop, and that outputs a pulse of pulse width determined according to a delay time of an electronic circuit of a delay time measurement target when provided with a signal for starting a delay measurement, and that, for an input pulse, outputs a pulse of pulse width determined according to the electronic circuit delay time; and
a counting section that counts a pulse number of pulses output from the pulse output section, wherein the electronic circuit delay measurement method includes:
inputting a pulse to the pulse output section as a signal to start a delay measurement;
acquiring a specific reduction time of the delay section;
reading a count value counted by the counting section until no more pulses are forthcoming from the pulse output section, when the pulse has been input in the inputting; and
calculating the electronic circuit delay time based on the specific reduction time of the delay section acquired at the acquiring and on the count value of the counting section read at the reading.

11. The electronic circuit delay measurement method of claim 10, wherein the reading that reads the count value counted by the counting section includes: reading count values of the counting section at respective fixed intervals and determines that a state exists in which no more pulses are forthcoming from the pulse output section when the read count values becomes the same count value.

12. A computer-readable recording medium having stored therein an electronic circuit delay measurement program employed for an electronic circuit delay measurement device comprising:
a delay section configured by a loop that reduces a pulse width of an input pulse by a specific reduction time and outputs the pulse, and that is connected such that the output pulse is employed as input;
a pulse output section that is provided in the delay section loop, and that outputs a pulse of pulse width determined according to a delay time of an electronic circuit of a delay time measurement target when provided with a signal for starting a delay measurement, and that, for an input pulse, outputs a pulse of pulse width determined according to the electronic circuit delay time; and
a counting section that counts a pulse number of pulses output from the pulse output section, wherein the electronic circuit delay measurement program causes a computer to execute processing, the processing including:
inputting a pulse to the pulse output section as a signal to start delay measurement;
acquiring a specific reduction time of the delay section;
reading a count value counted by the counting section until no more pulses are forthcoming from the pulse output section, when the pulse has been input in the inputting; and
calculating the electronic circuit delay time based on the specific reduction time of the delay section acquired at the acquiring and on the count value of the counting section read at the reading.
